(19) United States
(12) Patent Application Publication
(10) Pub. No.: US 2026/0330093 A1
(43) Pub. Date: Oct. 22, 2026

(54) METHOD AND SYSTEM FOR GENERATING DRIVING SIMULATION ENVIRONMENT OF UNMANNED MOVING OBJECT

(71) Applicant: MORAI INC., Seoul (KR)

(72) Inventors: Seung Jun LEE, Seoul (KR); Hwang JEON, Seoul (KR); Jun HONG, Seoul (KR); Jiwon JUNG, Seoul (KR)

(21) Appl. No.: 19/692,266

(22) Filed: May 29, 2026

Related U.S. Application Data
(63) Continuation of application No. PCT/KR2024/017812, filed on Nov. 12, 2024.

(30) Foreign Application Priority Data
Nov. 29, 2023 (KR) 10-2023-0169347

(51) Int. Cl. G06F 30/20; G06F 3/0482; G06F 3/04847

(52) U.S. Cl. CPC G06F 30/20; G06F 3/0482; G06F 3/04847

(57) ABSTRACT

A method of generating a driving simulation environment of an unmanned moving object includes receiving a first user input associated with a time of a driving simulation environment of an unmanned moving object, receiving a second user input associated with a weather condition of the driving simulation environment, and generating the driving simulation environment based on the first user input and the second user input.

### CROSS-REFERENCE TO RELATED APPLICATIONS

This application is a continuation of International Application No. PCT/KR2024/017812, filed Nov. 12, 2024, which claims the benefit of priority under 35 U.S.C. § 119(a) to Korean Patent Application No. 10-2023-0169347, filed Nov. 29, 2023, in the Korean Intellectual Property Office, the entire disclosures of which are incorporated herein by reference.

### TECHNICAL FIELD

Embodiments relate to a method and a system for generating a driving simulation environment of an unmanned moving object, and specifically, to a method and a system for generating the driving simulation environment based on a first user input associated with a time of the driving simulation environment of the unmanned moving object and a second user input associated with a weather condition of the driving simulation environment.

### BACKGROUND

Recently, as vehicle-related technologies such as IT, electrical, and electronic technologies develop, an autonomous driving technology utilizing all of the vehicle-related technologies is receiving attention. The autonomous driving technology may bring positive effects such as traffic safety improvement, traffic congestion relief, urban traffic efficiency improvement, and environmental problem resolution by making it possible to recognize an environment and move to a destination without a continuous control of a driver.

However, because the autonomous driving technology controls a moving object without an intervention of the driver, the autonomous driving technology is accompanied by many social problems such as safety regulations, and a verification according to many tests for solving the many social problems is required. However, because conventional technologies require mounting systems equipped with various driving devices and algorithms on the moving object and conducting a driving test on an actual road, the conventional technologies have a problem in that an effective autonomous driving performance may not be tested due to spatial constraints, and it is increasingly desirable to have the driving simulation environment for efficiently reproducing and testing various traffic conditions, weather conditions, and unexpected situations.

### TECHNICAL PROBLEM

The present disclosure provides a method and an apparatus (system) for generating the driving simulation environment of the unmanned moving object and a computer-readable non-transitory recording medium recording instructions to solve the above problems.

### SUMMARY

The present disclosure may be implemented in various ways including a method, an apparatus (system), or a computer-readable non-transitory recording medium recording instructions.

In some embodiments, a method of generating a driving simulation environment of an unmanned moving object, performed by at least one processor, may be provided. The method may include receiving a first user input associated with a time of a driving simulation environment of an unmanned moving object, receiving a second user input associated with a weather condition of the driving simulation environment, and generating the driving simulation environment based on the first user input and the second user input.

In some embodiments, the first user input may include a user input associated with a first interface controlling the time of the driving simulation environment. The first interface may include a first toggle switch. The time of the driving simulation environment is synchronized with a current time based on the first toggle switch being activated. A time control slider is output on the first interface based on the first toggle switch being deactivated. The time control slider is configured such that the time of the driving simulation environment is adjusted corresponding to a slider value.

In some embodiments, the second user input may include a user input associated with a second interface controlling the weather condition of the driving simulation environment. The second interface may include a second toggle switch. The weather condition of the driving simulation environment is synchronized with a current weather condition of a specific region based on the second toggle switch being activated. At least one weather control slider is output on the second interface based on the second toggle switch being deactivated.

In some embodiments, the second interface may include at least one preset button for changing to a preset weather condition.

In some embodiments, the at least one weather control slider may include a first slider controlling a rainfall amount of the driving simulation environment, and a second slider controlling a ground moisture amount of the driving simulation environment. The second slider is configured such that at least one of a number or a size of puddles existing on a ground of the driving simulation environment increases as a slider value increases, and at least one of a number or a size of puddles existing on the ground of the driving simulation environment decreases as the slider value decreases.

In some embodiments, the at least one weather control slider may include a third slider controlling a snowfall amount of the driving simulation environment, and a fourth slider controlling a snow accumulation amount of the driving simulation environment. The fourth slider is configured such that a depth of snow accumulated in the driving simulation environment increases as a slider value increases, and the depth of snow accumulated in the driving simulation environment decreases as the slider value decreases.

In some embodiments, the at least one weather control slider may include a fifth slider controlling a density and a volume of clouds existing in the driving simulation environment, and the clouds existing in the driving simulation environment are configured to spread out in an irregular radial shape around a specific reference position.

In some embodiments, the generated driving simulation environment is utilized for an autonomous driving simulation of the unmanned moving object, and the autonomous driving simulation is configured to recognize an object existing in the generated driving simulation environment, generate a control command associated with the unmanned moving object based on a recognition result of the object, and simulate an autonomous driving of the unmanned moving object based on the control command.

In some embodiments, a computer-readable non-transitory recording medium recording instructions for executing the aforementioned methods.

In some embodiments, an information processing system may include a communication module, a memory, and at least one processor connected to the memory and configured to execute at least one computer-readable program included in the memory. The at least one program may include instructions for receiving a first user input associated with a time of a driving simulation environment of an unmanned moving object, receiving a second user input associated with a weather condition of the driving simulation environment, and generating the driving simulation environment based on the first user input and the second user input.

### ADVANTAGEOUS EFFECTS

According to various embodiments of the present disclosure, a driving simulation environment synchronized with a current time and a current weather condition of a specific region may be generated through a toggle switch. Accordingly, even without specifically designing the driving simulation environment, the driving simulation environment reflecting the current time and the current weather condition of the specific region in real time may be generated.

According to various embodiments of the present disclosure, a weather condition of the driving simulation environment may be changed to a preset weather condition through a preset button. Accordingly, representative weather conditions such as a rainy state, a snowy state, and fog may be implemented without controlling detailed parameters of the driving simulation environment.

According to various embodiments of the present disclosure, a driving simulation environment of various times and weather conditions may be generated through an intuitive user interface (e.g., a slider, etc.). Accordingly, a driving simulation environment of various cases may be easily implemented without a complicated procedure by conveniently and quickly controlling each parameter related to a time and a weather.

According to various embodiments of the present disclosure, the generated driving simulation environment may be utilized to recognize an object existing in the driving simulation environment, generate a control command associated with the unmanned moving object based on a recognition result of the object, and simulate an autonomous driving of the unmanned moving object based on the control command. Accordingly, driving data under various conditions may be collected by replacing a test in an actual environment requiring a lot of time and resources, and a safety of an unmanned moving object (e.g., an autonomous vehicle, etc.) may be more efficiently verified.

Effects of the present disclosure are not limited to the above-mentioned effects, and other effects not mentioned may be clearly understood by a person having ordinary skill in the art to which the present disclosure pertains (referred to as a “person skilled in the art”) from the description of the claims.

### BRIEF DESCRIPTION OF THE DRAWINGS

Embodiments of the present disclosure will be described with reference to the accompanying drawings described below, wherein like reference numerals indicate like elements, but are not limited thereto.

FIG. 1 illustrates an example in which a driving simulation environment is generated according to an embodiment of the present disclosure.

FIG. 2 is a schematic view illustrating a configuration in which an information processing system according to an embodiment of the present disclosure is communicatively connected to a plurality of unmanned moving objects.

FIG. 3 illustrates an internal configuration of the information processing system according to an embodiment of the present disclosure.

FIG. 4 illustrates an example of a user interface associated with a driving simulation environment generation according to an embodiment of the present disclosure.

FIG. 5 illustrates an example in which a driving simulation environment is generated based on a user input associated with a time according to an embodiment of the present disclosure.

FIG. 6 illustrates an example in which a driving simulation environment is generated based on a user input associated with a weather condition according to an embodiment of the present disclosure.

FIG. 7 illustrates another example in which a driving simulation environment is generated based on a user input associated with a weather condition according to an embodiment of the present disclosure.

FIG. 8 illustrates another example in which a driving simulation environment is generated based on a user input associated with a weather condition according to an embodiment of the present disclosure.

FIG. 9 illustrates another example in which a driving simulation environment is generated based on a user input associated with a weather condition according to an embodiment of the present disclosure.

FIG. 10 illustrates another example in which a driving simulation environment is generated based on a user input associated with a weather condition according to an embodiment of the present disclosure.

FIG. 11 is a flowchart illustrating an example of an autonomous driving simulation method of an unmanned moving object according to an embodiment of the present disclosure.

FIG. 12 is a flowchart illustrating an example of a driving simulation environment generating method according to an embodiment of the present disclosure.

### DETAILED DESCRIPTION

Hereinafter, detailed contents for carrying out the present disclosure will be described in detail with reference to the accompanying drawings. In some embodiments, in the following description, detailed descriptions of well-known functions or configurations will be omitted if the detailed descriptions may unnecessarily obscure the subject matter of the present disclosure.

In the accompanying drawings, same or corresponding elements are given same reference numerals. In some embodiments, in the description of the following embodiments, redundantly describing the same or corresponding elements may be omitted. In some embodiments, even if a description of an element is omitted, the element is not intended to not be included in any embodiment.

Advantages and features of the disclosed embodiments, and a method of achieving the advantages and features will become apparent with reference to the embodiments described below in conjunction with the accompanying drawings. In some embodiments, the present disclosure is not limited to the embodiments disclosed below and may be implemented in various different forms, and the present embodiments are provided only to make the present disclosure complete and to completely inform a person skilled in the art of the scope of the invention.

Terms used in this specification will be briefly described, and the disclosed embodiments will be described in detail. As the terms used in this specification, general terms that are currently widely used as possible while considering functions in the present disclosure were selected, but this may vary according to an intention of a person working in a related field, precedents, the emergence of new technologies, and the like. In some embodiments, in a specific case, there is also a term arbitrarily selected by an applicant, and in this case, the meaning will be described in detail in the description of a corresponding invention. For example, a term used in the present disclosure should be defined based on the meaning of the term and the overall contents of the present disclosure, rather than a simple name of the term.

A singular expression in this specification includes a plural expression unless the context clearly indicates that it is a singular expression. In some embodiments, a plural expression includes a singular expression unless the context clearly indicates that it is a plural expression. Throughout the specification, when a part is said to include an element, this means that the part does not exclude another element but may further include another element unless there is a specific opposing description.

In some embodiments, a term ‘module’ or ‘unit’ used in the specification means a software or hardware element, and the ‘module’ or the ‘unit’ performs certain roles. In some embodiments, the ‘module’ or the ‘unit’ is not meant to be limited to software or hardware. The ‘module’ or the ‘unit’ may be configured to be in an addressable storage medium and may be configured to execute one or more processors. For example, as an example, the ‘module’ or the ‘unit’ may include elements such as software elements, object-oriented software elements, class elements, and task elements, and at least one of processes, functions, attributes, procedures, subroutines, segments of a program code, drivers, a firmware, a microcode, a circuit, data, a database, data structures, tables, arrays, or variables. Functions provided within the elements and the ‘modules,’ or the ‘units’ may be combined into a smaller number of elements and ‘modules’ or ‘units’ or may be further separated into additional elements and ‘modules’or ‘units’.

According to an embodiment of the present disclosure, the ‘module’ or the ‘unit’ may be implemented by a processor and a memory. The ‘processor’ should be interpreted broadly to include a general-purpose processor, a central processing unit (CPU), a microprocessor, a digital signal processor (DSP), a controller, a microcontroller, a state machine, and the like. In some environments, the ‘processor’ may refer to an application specific integrated circuit (ASIC), a programmable logic device (PLD), a field programmable gate array (FPGA), and the like. The ‘processor’ may also refer to a combination of processing devices, for example, a combination of a DSP and a microprocessor, a combination of a plurality of microprocessors, a combination of one or more microprocessors combined with a DSP core, or any other combination of such configurations. In some embodiments, the ‘memory’ should be interpreted broadly to include any electronic component capable of storing electronic information. The ‘memory’ may refer to various types of processor-readable media such as a random access memory (RAM), a read only memory (ROM), a non-volatile random access memory (NVRAM), a programmable read-only memory (PROM), an erasable programmable read-only memory (EPROM), an electrically erasable PROM (EEPROM), a flash memory, a magnetic or optical data storage device, registers, and the like. The memory is said to be in an electronic communication state with the processor if the processor may read information from the memory and/or write information to the memory. The memory integrated into the processor is in an electronic communication state with the processor.

In the present disclosure, a ‘display’ may refer to any display device associated with a computing device (e.g., a driving environment simulation generating apparatus, etc.), for example, the ‘display’ may refer to any display device capable of displaying any information/data provided from the computing device or controlled by the computing device.

In the present disclosure, a ‘system’ may include at least one of a server device and a cloud device but is not limited thereto. For example, the ‘system’ may include one or more server devices. As another example, the ‘system’ may include one or more cloud devices. As another example, the ‘system’ may operate with a server device and a cloud device configured together.

In the present disclosure, an ‘unmanned moving object (unmanned vehicle)’ may refer to a mechanical device that is not directly controlled by a person but moves through a remote control or an autonomous system. For example, the ‘unmanned moving object’ may include an autonomous car, an Unmanned Ground Vehicle (UGV), an Unmanned Aerial Vehicle (UAV), an Unmanned Surface Vehicle (USV), and the like.

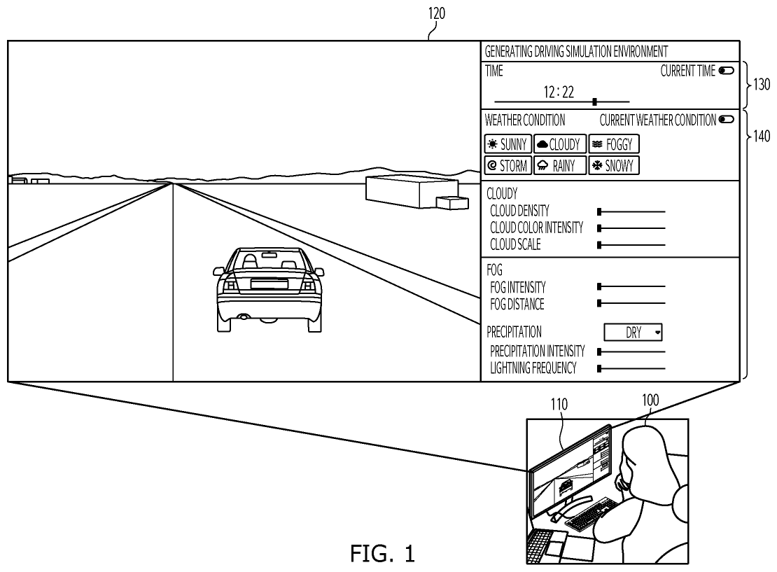

FIG. 1 illustrates an example in which a driving simulation environment is generated according to an embodiment of the present disclosure. As illustrated, a user (e.g., an unmanned moving object (or vehicle) manufacturer, a technology developer, a researcher, etc.) 100 may generate a driving simulation environment of an unmanned moving object through a driving environment simulation generating apparatus 110. The driving environment simulation generating apparatus 110 may output a user interface 120 associated with a driving simulation environment generation through a display.

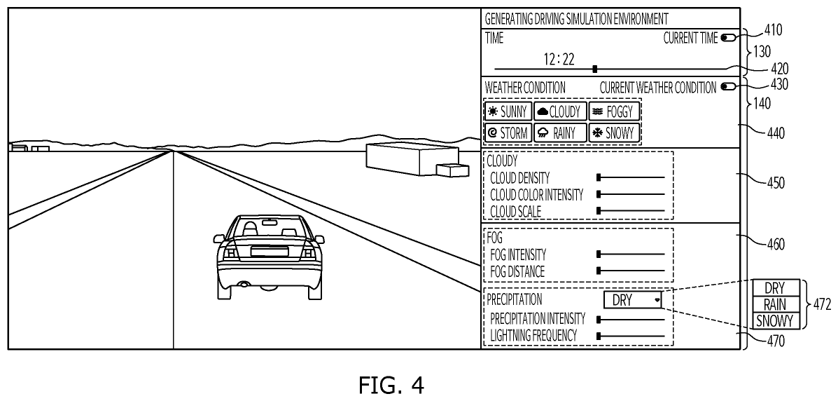

According to an embodiment, the driving environment simulation generating apparatus 110 may receive a first user input associated with a time of the driving simulation environment of the unmanned moving object. For example, the user interface 120 associated with the driving simulation environment generation may include a first interface 130 controlling the time of the driving simulation environment, and the driving environment simulation generating apparatus 110 may receive a user input (e.g., a touch input on a toggle switch, a drag input on a slider, etc.) associated with the first interface 130. Detailed contents on a configuration of the first interface 130 will be described below with reference to FIG. 4.

According to an embodiment, the driving environment simulation generating apparatus 110 may receive a second user input associated with a weather condition of the driving simulation environment of the unmanned moving object. For example, the user interface 120 associated with the driving simulation environment generation may include a second interface 140 for controlling the weather conditions of the driving simulation environment, and the driving environment simulation generating apparatus 110 may receive a user input associated with the second interface 140. Detailed contents on a configuration of the second interface 140 will be described below with reference to FIG. 4.

According to an embodiment, the driving environment simulation generating apparatus 110 may generate the driving simulation environment based on the first user input and the second user input. The driving environment simulation generating apparatus 110 may set a detailed parameter of the driving simulation environment according to the first user input and the second user input and may implement the driving simulation environment of the time and the weather condition corresponding to the detailed parameter based on the set detailed parameter. For example, the driving environment simulation generating apparatus 110 may implement the driving simulation environment in a rainy state in which a puddle reflecting a surrounding object (e.g., a building, a vehicle, a vegetation, a pedestrian, etc.) exists. As another example, the driving environment simulation generating apparatus 110 may implement the driving simulation environment in a snowy state in which snow is accumulated on the surrounding object and an appearance of the surrounding object is partially changed. As another example, the driving environment simulation generating apparatus 110 may implement the driving simulation environment in a foggy state in which a part of a field of view is obscured by fog. As another example, the driving environment simulation generating apparatus 110 may implement the driving simulation environment in a night state in which a surrounding field of view is dark.

As described above, the user may generate the driving simulation environment of various time zones and weather conditions through an intuitive user interface (e.g., a slider, etc.). Accordingly, the user may easily implement the driving simulation environment of various cases without a complicated procedure.

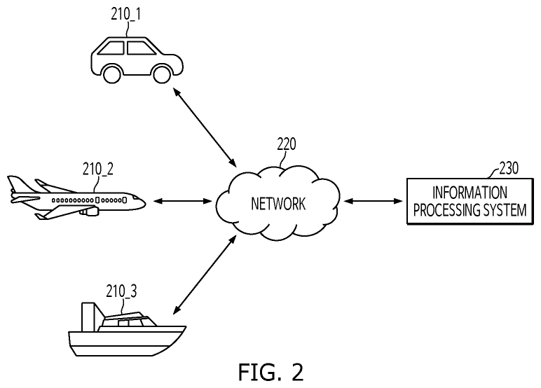

FIG. 2 is a schematic view illustrating a configuration in which an information processing system 230 according to an embodiment of the present disclosure is communicatively connected to a plurality of unmanned moving objects 210_1, 210_2, and 210_3. Although it is illustrated in FIG. 2 that the plurality of unmanned moving objects 210_1, 210_2, and 210_3 communicate with the information processing system 230 through a network 220, the present disclosure is not limited thereto, and a communication unit mounted on the plurality of unmanned moving objects 210_1, 210_2, and 210_3 may communicate with another unmanned moving object and an external device. Here, a communication may include a Vehicle to Everything (V2X) communication. The information processing system 230 may include the driving environment simulation generating apparatus 110 of FIG. 1. In some embodiments, the plurality of unmanned moving objects 210_1, 210_2, and 210_3 may be an actual unmanned moving object including a simulator performing a simulation in a virtual driving simulation environment or a virtual unmanned moving object existing in the virtual driving simulation environment.

In an embodiment, the information processing system 230 may include one or more server devices and/or a database capable of storing, providing, and executing a computer-executable program (e.g., a downloadable application) and data related to a driving environment simulation generation, or one or more distributed computing devices and/or a distributed database based on a cloud computing service. The information processing system 230 may provide information corresponding to a signal input through an application (e.g., an application related to a driving simulation environment generation, etc.) or perform a corresponding processing. For example, the information processing system 230 may provide the generated driving simulation environment to the plurality of unmanned moving objects 210_1, 210_2, and 210_3 through any application related to the driving simulation environment generation. The plurality of unmanned moving objects 210_1, 210_2, and 210_3 may recognize an object existing in the provided driving simulation environment, generate a control command based on a recognition result of the object, and perform an autonomous driving simulation based on the control command.

The information processing system 230 may communicate with the plurality of unmanned moving objects 210_1, 210_2, and 210_3 through the network 220. The network 220 may be configured to enable a communication between the plurality of unmanned moving objects 210_1, 210_2, and 210_3 and the information processing system 230. The network 220 may include a wired network such as an Ethernet, a Power Line Communication, a telephone line communication device, and an RS-serial communication, a mobile communication network, a wireless network such as a Wireless LAN (WLAN), a Wi-Fi, a Bluetooth, and a ZigBee, or a combination thereof according to an installation environment. A communication method is not limited, and may include not only a communication method utilizing a communication network (e.g., a mobile communication network, a wired Internet, a wireless Internet, a broadcasting network, a satellite network, etc.) that the network 220 may include, but also a short-range wireless communication between the plurality of unmanned moving objects 210_1, 210_2, and 210_3.

Although it is illustrated in FIG. 2 that three unmanned moving objects 210_1, 210_2, and 210_3 communicate with the information processing system 230 through the network 220, the present disclosure is not limited thereto, and any number of unmanned moving objects may be configured to communicate with the information processing system 230 through the network 220.

Although FIG. 2 illustrates a distributed processing structure in which the information processing system 230 generates the driving simulation environment and the plurality of unmanned moving objects 210_1, 210_2, and 210_3 perform the driving simulation using the generated driving simulation environment, the present disclosure is not limited thereto, and the information processing system 230 may perform both the driving simulation environment generation and the driving simulation of the plurality of unmanned moving objects 210_1, 210_2, and 210_3.

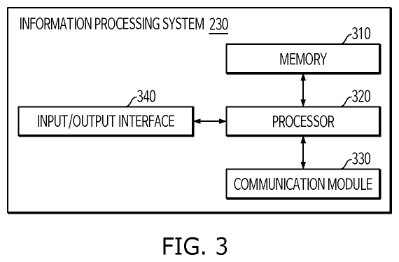

FIG. 3 illustrates an internal configuration of the information processing system 230 according to an embodiment of the present disclosure. The information processing system 230 may include the driving environment simulation generating apparatus 110 of FIG. 1. The information processing system 230 may include a memory 310, a processor 320, a communication module 330, and an input/output interface 340. The information processing system 230 may be configured to communicate information and/or data through a network using the communication module 330.

The memory 310 may include any computer-readable recording medium. According to an embodiment, the memory 310 may include a non-transitory computer-readable recording medium, which may include a permanent mass storage device such as a read only memory (ROM), a disk drive, a solid state drive (SSD), a flash memory, and the like. As another example, a permanent mass storage device such as a ROM, an SSD, a flash memory, a disk drive, and the like may be included in the information processing system 230 as a separate permanent storage device distinguished from the memory 310. In some embodiments, an operating system and at least one program code (e.g., a code for a process execution for a device, etc.) may be stored in the memory 310.

Such software elements may be loaded from a computer-readable recording medium separate from the memory 310. Such a separate computer-readable recording medium may include a recording medium connectable directly to the information processing system 230, for example, the separate computer-readable recording medium may include a computer-readable recording medium such as a floppy drive, a disk, a tape, a DVD/CD-ROM drive, a memory card, and the like. As another example, the software elements may be loaded into the memory 310 through the communication module 330 rather than the separate computer-readable recording medium. For example, at least one program may be loaded into the memory 310 based on a computer program (e.g., a program for a process execution for a device, etc.) installed by files provided through the communication module 330 by developers or a file distribution system that distributes an installation file of an application.

The processor 320 may be configured to process instructions of a computer program by performing basic arithmetic, logic, and input/output operations. The instructions may be provided to a user terminal (not shown) or another external system by the memory 310 or the communication module 330. For example, the processor 320 may provide the generated driving simulation environment to the plurality of unmanned moving objects 210_1, 210_2, and 210_3.

The communication module 330 may provide a configuration or a function for an unmanned moving object (not shown) and the information processing system 230 to communicate with each other through a network and may provide a configuration or a function for the information processing system 230 to communicate with an external system (e.g., a separate cloud system, etc.). For example, a control signal, an instruction, data, etc. provided according to a control of the processor 320 of the information processing system 230 may be transmitted to the unmanned moving object and/or the external system through the communication module 330 and a network, and through a communication module of the unmanned moving object and/or the external system. For example, the processor 320 may transmit the generated driving simulation environment to the unmanned moving object through the communication module 330.

In some embodiments, the input/output interface 340 of the information processing system 230 may be a means for interfacing with an apparatus for input or output (not shown) connected to the information processing system 230 or included within the information processing system 230. Although the input/output interface 340 is illustrated as an element configured separately from the processor 320 in FIG. 3, the present disclosure is not limited thereto, and the input/output interface 340 may be configured to be included in the processor 320. The information processing system 230 may include more elements than the elements of FIG. 3. However, there is no need to clearly illustrate most prior art elements.

The processor 320 of the information processing system 230 may be configured to manage, process, and/or store information and/or data received from the plurality of unmanned moving objects 210_1, 210_2, and 210_3 and/or a plurality of external systems. According to an embodiment, the processor 320 may execute a main process of the application and a plurality of sub-processes for a plurality of devices associated with the application in response to an application execution command.

FIG. 4 illustrates an example of a user interface associated with a driving simulation environment generation according to an embodiment of the present disclosure. The user interface of FIG. 4 may be the user interface 120 output on the display of the driving environment simulation generating apparatus 110 of FIG. 1. The user interface may include the first interface 130 associated with a time of a driving simulation environment and the second interface 140 associated with a weather condition of the driving simulation environment.

According to an embodiment, the first interface 130 may include a first toggle switch 410 for synchronizing the time of the driving simulation environment with a current time. The first toggle switch 410 may be activated by a user input (e.g., a touch input, etc.). When the first toggle switch 410 is activated, the time of the driving simulation environment may be synchronized with the current time. In this case, the current time may be a current time set in the driving environment simulation generating apparatus 110 or a current time of an actual place when the driving simulation environment is rendered based on the actual place. In some embodiments, when the first toggle switch 410 is activated, a time control slider 420 to be described below may be deactivated and may not be output on the first interface 130. When the time of the driving simulation environment is synchronized with the current time, the driving simulation environment may be changed/rendered according to the synchronized time.

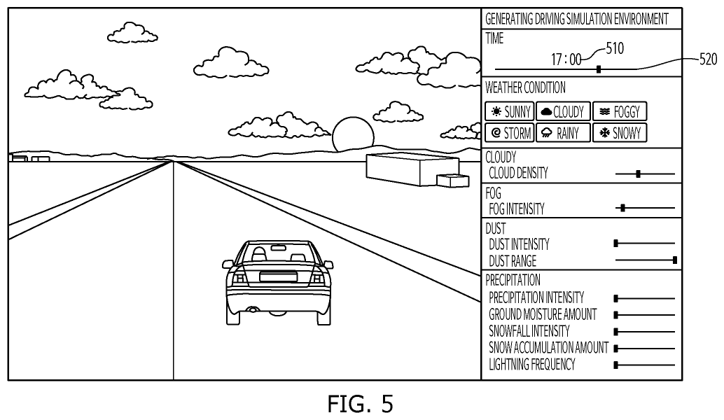

According to an embodiment, when the first toggle switch 410 is deactivated, the time control slider 420 may be output on the first interface 130. The time control slider 420 may have a slider value adjusted by a user input on a slider handle (e.g., a drag, etc.) or a user input on a slider track (e.g., a touch input, etc.), and the time control slider 420 may be configured such that the time of the driving simulation environment is adjusted corresponding to the slider value. Detailed contents on this will be described below with reference to FIG. 5.

According to an embodiment, the second interface 140 may include a second toggle switch 430 for synchronizing the weather condition of the driving simulation environment with a current weather condition of a specific region. The second toggle switch 430 may be activated by a user input (e.g., a touch input, etc.) similarly to the first toggle switch 410.

According to an embodiment, when the second toggle switch 430 is activated, the weather condition of the driving simulation environment may be synchronized with the current weather condition of the specific region. For example, when the second toggle switch 430 is activated, data associated with the current weather condition of the specific region (e.g., OpenWeather API, Korea Meteorological Administration short-term forecast API, etc.) may be received from an external system (e.g., a Korea Meteorological Administration homepage, etc.), and the current weather condition of the specific region may be implemented in the driving simulation environment by setting a detailed parameter associated with the weather condition based on the data. In this case, the specific region may be a location or position of the driving environment simulation generating apparatus 110 reflecting GPS information of the driving environment simulation generating apparatus 110 or an actual region when the driving simulation environment is rendered based on the actual region. In some embodiments, when the second toggle switch 430 is activated, a preset button 440 and a plurality of weather control slider sets 450, 460, and 470 to be described below may be deactivated and may not be output on the second interface 140. When the weather condition of the driving simulation environment is synchronized with the current weather condition, the driving simulation environment may be changed/rendered according to the synchronized weather condition.

According to an embodiment, when the second toggle switch 430 is deactivated, the preset button 440 may be output on the second interface 140. The preset button 440 may include a plurality of buttons related to a weather condition, and a weather state of the driving simulation environment may be changed in response to a user input (e.g., a touch input, etc.) on at least one of the plurality of buttons. For example, an initial weather condition of the driving simulation environment may be a sunny state, and when a user selects a rainy state setting button (rainy), the weather state of the driving simulation environment may be changed to a rainy state. Along with this, a slider of a weather control slider set associated with the rainy state may be automatically set.

Although it is illustrated in FIG. 4 that the preset button 440 includes a sunny state setting button (sunny), a button for a cloudy state (cloudy), a foggy state setting button (foggy), a storm state setting button (storm), a rainy state setting button (rainy), and a snowy state setting button (snowy), the preset button 440 is not limited thereto, and may include buttons for various weather conditions. For example, the preset button 440 may include an overcast button (overcast), a broken button (broken), and a scattered button (scattered), which are buttons associated with a state of clouds. The overcast button may refer to a button changing a weather condition to a state in which an entire sky is completely covered with clouds. The broken button may refer to a button changing a weather condition to a state in which clouds cover a substantial part of the sky but do not completely cover the sky (a state in which clouds cover about 50% to 90% of the sky). The scattered button may refer to a button changing a weather condition to a state in which clouds cover only a part of the sky (a state in which clouds cover about 10% to 50% of the sky).

According to an embodiment, when the second toggle switch 430 is deactivated, the plurality of weather control slider sets 450, 460, and 470 may be output on the second interface 140. The plurality of weather control slider sets 450, 460, and 470 may be a slider set capable of controlling a detailed parameter per weather condition of the driving simulation environment.

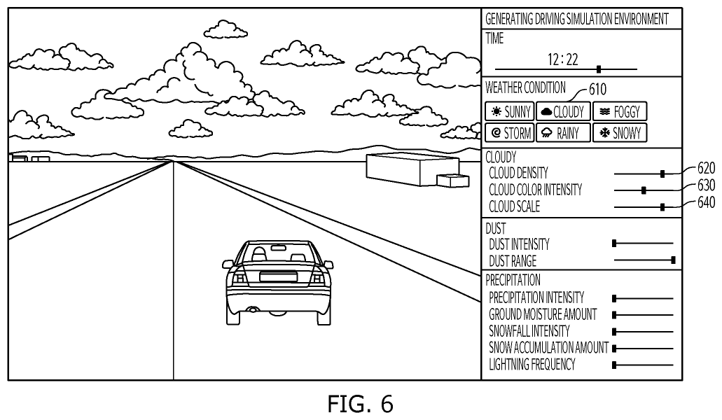

According to an embodiment, the plurality of weather control slider sets 450, 460, and 470 may include a first slider set 450 associated with a cloudy state. The first slider set 450 may include a slider capable of controlling a density of the clouds (density), a slider capable of controlling a color intensity of the clouds (intensity), and a slider capable of controlling a volume of the clouds (scale). Detailed contents on this will be described below with reference to FIG. 6.

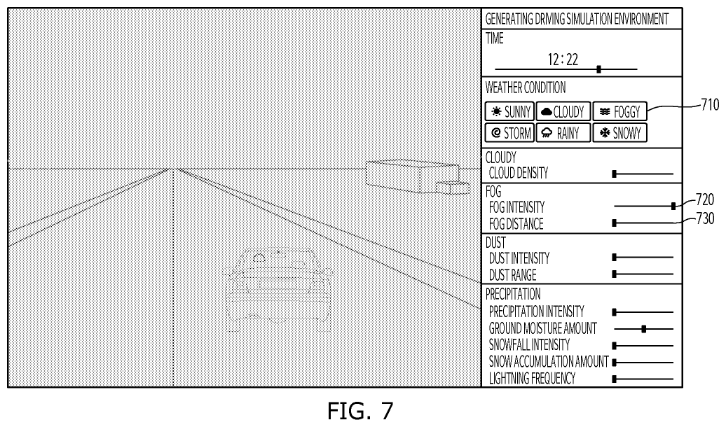

According to an embodiment, the plurality of weather control slider sets 450, 460, and 470 may include a second slider set 460 associated with a foggy state. The second slider set 460 may include a slider capable of controlling an intensity of the fog (intensity), and a slider capable of controlling a starting point distance of the fog (distance). Detailed contents on this will be described below with reference to FIG. 7.

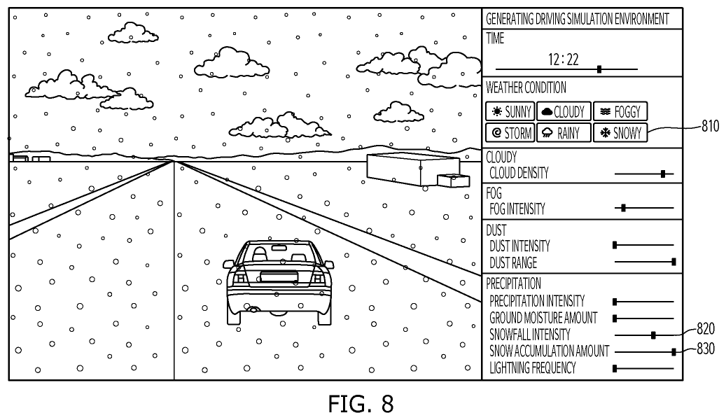

According to an embodiment, the plurality of weather control slider sets 450, 460, and 470 may include a third slider set 470 associated with a precipitation state. The third slider set 470 may include a precipitation type selection area 472. The precipitation type selection area 472 may be an area in which a type of precipitation (or precipitation condition) falling in the driving simulation environment may be selected and may output an option for selecting a dry state (dry), a rainy state (rainy), and a snowy state (snow) in a drop-down format. In some embodiments, the third slider set 470 may include a slider capable of controlling a precipitation amount (intensity) and a slider controlling a frequency of lightning (lightning). Detailed contents on this will be described below with reference to FIGS. 8 to 10.

According to an embodiment, the plurality of weather control slider sets 450, 460, and 470 may further include a fourth slider set associated with a dusty state. The dusty state may refer to a weather condition in which fine dust, yellow dust (Asian dust), or sand particles are suspended in an airspace of the driving simulation environment, thereby affecting a visibility of a virtual unmanned moving object or a virtual camera attached to the virtual unmanned moving object. The fourth slider set may include a slider capable of controlling a dust intensity and a slider capable of controlling a dust range. The slider capable of controlling the dust intensity may be configured such that a concentration of dust particles existing in the driving simulation environment increases as a slider value increases, and the concentration of dust particles existing in the driving simulation environment decreases as the slider value decreases. The slider capable of controlling the dust range may be configured such that a spatial extent or a coverage area in which dust particles are distributed in the driving simulation environment increases as a slider value increases, and the spatial extent or the coverage area in which dust particles are distributed in the driving simulation environment decreases as the slider value decreases. In this case, the slider value of each of the sliders included in the fourth slider set may be between 0 and 1 or between 0% and 100%. Detailed contents on this will be described below with reference to the corresponding drawings.

According to an embodiment, similarly to the time control slider 420, the plurality of weather control slider sets 450, 460, and 470 may have a slider value adjusted by a user input on a slider handle (e.g., a drag, etc.) or a user input on a slider track (e.g., a touch input, etc.), and the plurality of weather control slider sets 450, 460, and 470 may be configured such that the weather condition of the driving simulation environment is adjusted corresponding to the slider value.

Although detailed configurations of the first interface 130 and the second interface 140 are illustrated in FIG. 4, the first interface 130 and the second interface 140 are not limited thereto, and a partial configuration may be omitted, or an additional configuration may be included. For example, the first interface 130 and the second interface 140 may include an input field in which a specific slider value may be input. As another example, although it is illustrated that the third slider set 470 of the second interface 140 includes the precipitation type selection area 472, the slider capable of controlling a precipitation amount (intensity), and the slider controlling a frequency of lightning (lightning), the third slider set 470 is not limited thereto, and the third slider set 470 may include a plurality of sliders capable of controlling detailed parameters of each of a rainy state and a snowy state.

As in the above-described configuration, a user interface associated with a driving simulation environment generation of a driving environment simulation generating apparatus may include a toggle switch, and a user may generate a driving simulation environment synchronized with a current time and/or a current weather condition of a specific region through the toggle switch using the driving environment simulation generating apparatus. Accordingly, the user may generate a driving simulation environment reflecting the current time and the current weather condition of the specific region in real time even without specifically designing the driving simulation environment.

In some embodiments, a user may change a weather condition of a driving simulation environment to a preset weather condition through a preset button. Accordingly, the user may implement representative or typical weather conditions such as a rainy state, a snowy state, and fog without controlling detailed parameters of the driving simulation environment.

In some embodiments, a user may generate a driving simulation environment of various times of day (or time zones) and weather conditions through an intuitive user interface (e.g., a slider, etc.). Accordingly, the user may easily implement a driving simulation environment of various cases without a complicated procedure by conveniently and quickly controlling detailed parameters related to a time and a weather.

FIG. 5 illustrates an example in which a driving simulation environment is generated based on a user input associated with a time according to an embodiment of the present disclosure. According to an embodiment, a driving environment simulation generating apparatus (e.g., the driving environment simulation generating apparatus 110 of FIG. 1, etc.) may set a time zone of a driving simulation environment in response to a user input on a time control slider 520. For example, the driving environment simulation generating apparatus may receive a user input of dragging a handle of the time control slider 520 to be positioned at a specific slider value and may set the time zone of the driving simulation environment to a time zone corresponding to the specific slider value. In this case, the driving environment simulation generating apparatus may output a time corresponding to the specific slider value in a time display area 510.

According to an embodiment, the driving environment simulation generating apparatus may generate the driving simulation environment based on the set time zone. For example, the driving environment simulation generating apparatus may determine a position of the sun existing in the driving simulation environment based on a position (e.g., a latitude, a longitude, an altitude, etc.) of a virtual unmanned moving object located within the driving simulation environment or a virtual camera attached to the virtual unmanned moving object. In this case, when the position of the sun enters a field of view of the virtual unmanned moving object or the virtual camera attached to the virtual unmanned moving object, the sun may be rendered in an airspace of the driving simulation environment. In some embodiments, the driving environment simulation generating apparatus may adjust a brightness of the driving simulation environment based on the determined position of the sun and may render shadows of objects existing in the driving simulation environment.

FIG. 6 illustrates an example in which a driving simulation environment is generated based on a user input associated with a weather condition according to an embodiment of the present disclosure. According to an embodiment, a driving environment simulation generating apparatus (e.g., the driving environment simulation generating apparatus 110 of FIG. 1, etc.) may change a weather condition of a driving simulation environment to a cloudy state in which clouds spreading out in an irregular radial shape around a reference position exist in response to a user input (e.g., a click, a touch input, etc.) on a cloudy state setting button 610 among preset buttons.

Additionally or alternatively, the driving environment simulation generating apparatus may change the weather condition of the driving simulation environment to a cloudy state in response to a user input on a slider set associated with the cloudy state. For example, the driving environment simulation generating apparatus may receive a user input of dragging a handle of each of a plurality of sliders 620, 630, and 640 existing in the slider set associated with the cloudy state to be positioned at a specific slider value. The driving environment simulation generating apparatus may change the weather condition of the driving simulation environment to the cloudy state in which clouds spreading out in an irregular radial shape around a reference position exist based on the received user input, and may control a shape and/or a volume of clouds existing in an airspace of the driving simulation environment to correspond to a slider value of each of the plurality of sliders 620, 630, and 640.

According to an embodiment, the slider set associated with the cloudy state may include the slider 620 capable of controlling a density of the clouds. As a slider value of the slider 620 increases, reference positions of the clouds existing in the airspace of the driving simulation environment may be densely arranged, and reference positions of the clouds arranged per reference area or reference volume may increase. On the other hand, as the slider value decreases, the reference positions of the clouds existing in the airspace of the driving simulation environment may be scattered and arranged, and reference positions of the clouds arranged per reference area or reference volume may decrease. In this case, the slider value of the slider 620 may be between 0 and 1 or between 0% and 100%.

According to an embodiment, the slider set associated with the cloudy state may include the slider 630 capable of controlling a color intensity of the clouds. As a slider value of the slider 630 increases, a brightness of the clouds existing in the airspace of the driving simulation environment may increase. On the other hand, as the slider value decreases, the brightness of the clouds existing in the airspace of the driving simulation environment may decrease. In this case, the slider value of the slider 630 may be between 0 and 1 or between 0% and 100%.

According to an embodiment, the slider set associated with the cloudy state may include the slider 640 capable of controlling a volume of the clouds. As a slider value of the slider 640 increases, a volume of the clouds existing in the airspace of the driving simulation environment may increase. On the other hand, as the slider value decreases, the volume of the clouds existing in the airspace of the driving simulation environment may decrease. In this case, the slider value of the slider 640 may be between 0 and 1 or between 0% and 100%.

FIG. 7 illustrates another example in which a driving simulation environment is generated based on a user input associated with a weather condition according to an embodiment of the present disclosure. According to an embodiment, a driving environment simulation generating apparatus (e.g., the driving environment simulation generating apparatus 110 of FIG. 1, etc.) may change a weather condition of a driving simulation environment to a foggy state in response to a user input (e.g., a click, a touch input, etc.) on a foggy state setting button 710 among preset buttons.

Additionally or alternatively, the driving environment simulation generating apparatus may change the weather condition of the driving simulation environment to a foggy state in response to a user input on a slider set associated with the foggy state. For example, the driving environment simulation generating apparatus may receive a user input of dragging a handle of each of a plurality of sliders 720 and 730 existing in the slider set associated with the foggy state to be positioned at a specific slider value. The driving environment simulation generating apparatus may change the weather condition of the driving simulation environment to the foggy state based on the received user input and may control an intensity and/or a starting point of fog existing in the driving simulation environment to correspond to a slider value of each of the plurality of sliders 720 and 730.

According to an embodiment, the slider set associated with the foggy state may include the slider 720 capable of controlling an intensity of the fog. As a slider value of the slider 720 increases, an intensity of the fog existing in the driving simulation environment may increase. On the other hand, as the slider value decreases, the intensity of the fog existing in the driving simulation environment may decrease. In this case, the slider value of the slider 720 may be between 0 and 1 or between 0% and 100%.

According to an embodiment, the slider set associated with the foggy state may include the slider 730 capable of controlling a starting point of the fog. As a slider value of the slider 730 increases, a starting point of the fog existing in the driving simulation environment may move further away. On the other hand, as the slider value decreases, the starting point of the fog existing in the driving simulation environment may move closer. In this case, the slider value of the slider 730 may be between 0 and 1 or between 0% and 100%.

FIG. 8 illustrates another example in which a driving simulation environment is generated based on a user input associated with a weather condition according to an embodiment of the present disclosure. According to an embodiment, a driving environment simulation generating apparatus (e.g., the driving environment simulation generating apparatus 110 of FIG. 1, etc.) may change a weather condition of a driving simulation environment to a snowy state in response to a user input (e.g., a click, a touch input, etc.) on a snowy state setting button 810 among preset buttons.

Additionally or alternatively, the driving environment simulation generating apparatus may change the weather condition of the driving simulation environment to a snowy state in response to a user input on a slider set associated with the snowy state. For example, the driving environment simulation generating apparatus may receive a user input of dragging a handle of each of a plurality of sliders 820 and 830 existing in the slider set associated with the snowy state to be positioned at a specific slider value. The driving environment simulation generating apparatus may change the weather condition of the driving simulation environment to the snowy state based on the received user input and may control a snowfall amount and/or a snow accumulation amount of the driving simulation environment to correspond to a slider value of each of the plurality of sliders 820 and 830.

According to an embodiment, the slider set associated with the snowy state may include the slider 820 capable of controlling a snowfall amount. As a slider value of the slider 820 increases, an amount of snow falling in the driving simulation environment may increase. On the other hand, as the slider value decreases, the amount of snow falling in the driving simulation environment may decrease. In this case, the slider value of the slider 820 may be between 0 and 1 or between 0% and 100%.

According to an embodiment, the slider set associated with the snowy state may include the slider 830 capable of controlling a snow accumulation amount. As a slider value of the slider 830 increases, a depth of snow accumulated in the driving simulation environment may increase. On the other hand, as the slider value decreases, the depth of snow accumulated in the driving simulation environment may decrease. In this case, the slider value of the slider 830 may be between 0 and 1 or between 0% and 100%. According to such a configuration, various weather environments may be generated, such as a situation where a current snowfall amount is small, but a snow accumulation amount is large, or a situation where a current snowfall amount is large, but a snow accumulation amount is small.

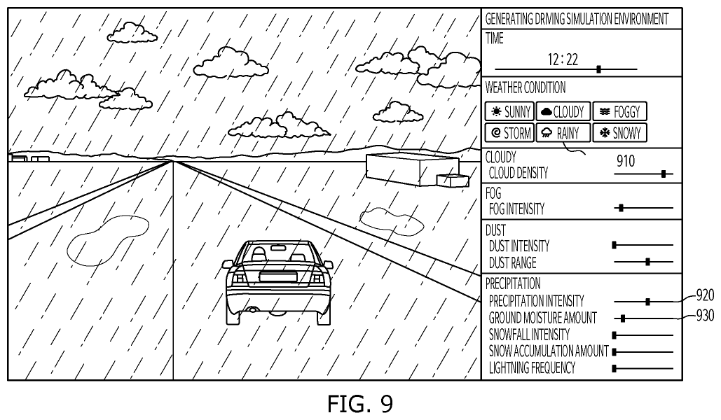

FIG. 9 illustrates another example in which a driving simulation environment is generated based on a user input associated with a weather condition according to an embodiment of the present disclosure. According to an embodiment, a driving environment simulation generating apparatus (e.g., the driving environment simulation generating apparatus 110 of FIG. 1, etc.) may change a weather condition of a driving simulation environment to a rainy state in response to a user input (e.g., a click, a touch input, etc.) on a rainy state setting button 910 among preset buttons.

Additionally or alternatively, the driving environment simulation generating apparatus may change the weather condition of the driving simulation environment to a rainy state in response to a user input on a slider set associated with the rainy state. For example, the driving environment simulation generating apparatus may receive a user input of dragging a handle of each of a plurality of sliders 920 and 930 existing in the slider set associated with the rainy state to be positioned at a specific slider value. The driving environment simulation generating apparatus may change the weather condition of the driving simulation environment to the rainy state based on the received user input and may control a rainfall amount and/or a ground moisture amount of the driving simulation environment to correspond to a slider value of each of the plurality of sliders 920 and 930.

According to an embodiment, the slider set associated with the rainy state may include the slider 920 capable of controlling a rainfall amount. As a slider value of the slider 920 increases, an amount of rain falling in the driving simulation environment may increase. On the other hand, as the slider value decreases, the amount of rain falling in the driving simulation environment may decrease. In this case, the slider value of the slider 920 may be between 0 and 1 or between 0% and 100%.

According to an embodiment, the slider set associated with the rainy state may include the slider 930 capable of controlling a ground moisture amount. As a slider value of the slider 930 increases, at least one of a number or a size of puddles existing on a ground of the driving simulation environment may increase. On the other hand, as the slider value decreases, at least one of a number or a size of puddles existing on the ground of the driving simulation environment may decrease. In this case, the slider value of the slider 930 may be between 0 and 1 or between 0% and 100%. According to such a configuration, various weather environments may be generated, such as a situation where a current rainfall amount is small but there are many puddles on the ground or/and a size of a puddle is large, or a situation where a current rainfall amount is large but there are few puddles on the ground or/and a size of a puddle is small.

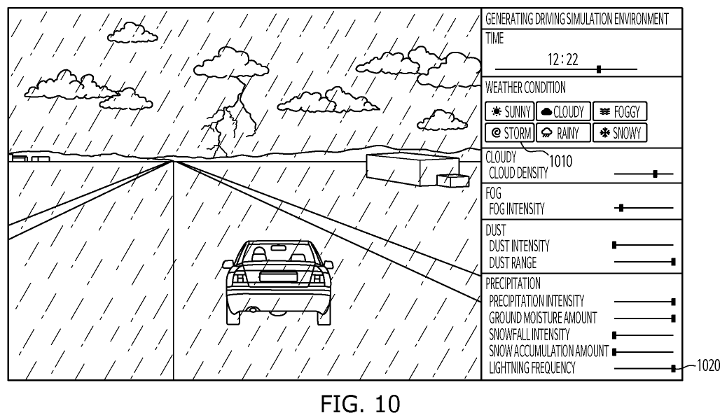

FIG. 10 illustrates another example in which a driving simulation environment is generated based on a user input associated with a weather condition according to an embodiment of the present disclosure. According to an embodiment, a driving environment simulation generating apparatus (e.g., the driving environment simulation generating apparatus 110 of FIG. 1, etc.) may change a weather condition of a driving simulation environment to a storm state in response to a user input (e.g., a click, a touch input, etc.) on a storm state setting button 1010 among preset buttons.

Additionally or alternatively, the driving environment simulation generating apparatus may change the weather condition of the driving simulation environment to a storm state in response to a user input on a slider set associated with the storm state. For example, the driving environment simulation generating apparatus may receive a user input of dragging a handle of a slider 1020 existing in the slider set associated with the storm state to be positioned at a specific slider value. The driving environment simulation generating apparatus may change the weather condition of the driving simulation environment to the storm state based on the received user input and may control aspects such as a frequency of lightning of the driving simulation environment to correspond to a slider value of the slider 1020.

According to an embodiment, the slider set associated with the storm state may include the slider 1020 capable of controlling a frequency of lightning. As a slider value of the slider 1020 increases, a frequency of a lightning phenomenon occurring in the driving simulation environment may increase. On the other hand, as the slider value decreases, the frequency of the lightning phenomenon occurring in the driving simulation environment may decrease. In this case, the slider value of the slider 1020 may be between 0 and 1 or between 0% and 100%.

According to an embodiment, a driving environment simulation generating apparatus (e.g., the driving environment simulation generating apparatus 110 of FIG. 1, etc.) may change a weather condition of a driving simulation environment to a dusty state in response to a user input on a slider set associated with the dusty state. For example, the driving environment simulation generating apparatus may receive a user input of dragging a handle of each of a plurality of sliders existing in the slider set associated with the dusty state to be positioned at a specific slider value. The driving environment simulation generating apparatus may change the weather condition of the driving simulation environment to the dusty state based on the received user input and may control a dust intensity and/or a dust range of the driving simulation environment to correspond to a slider value of each of the plurality of sliders. According to such a configuration, various weather environments may be generated, such as a situation where a dust concentration is high, but a dust distribution range is locally limited, or a situation where a dust concentration is moderate, but dust is widely distributed across a broad area of the driving simulation environment.

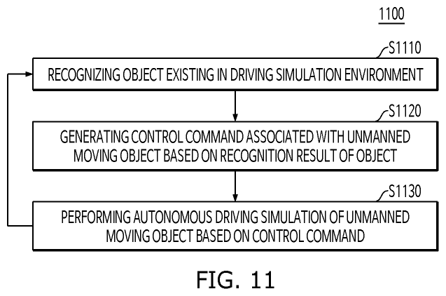

FIG. 11 is a flowchart illustrating an example of an autonomous driving simulation method 1100 of an unmanned moving object according to an embodiment of the present disclosure. In an embodiment, the method 1100 may be performed by a simulator performing an autonomous driving simulation of an unmanned moving object.

The method 1100 may be initiated by recognizing an object existing in a driving simulation environment (S1110). In an embodiment, the simulator may receive a generated driving simulation environment from a driving simulation environment generating apparatus (system). As described above in FIGS. 4 to 10, a time and a weather condition of the driving simulation environment may be changed by a user input on a user interface, and accordingly, an object in the driving simulation environment may also be modified and exist. For example, when the driving simulation environment is a snowy state, the object in the driving simulation environment may be in a state covered with snow.

In an embodiment, an object recognition result may be generated by recognizing an object (e.g., a road, a lane, a traffic light, an obstacle, a pedestrian, etc.) existing in the driving simulation environment through a virtual camera (e.g., a virtual camera attached to a virtual unmanned moving object, etc.) existing in the driving simulation environment. For example, the simulator may modify a virtual camera image by adjusting a characteristic (e.g., a focal length, a distortion, an aberration, etc.) of the virtual camera, and may generate the object recognition result by applying an image processing algorithm to the modified virtual camera image.

Then, the simulator may generate a control command associated with the unmanned moving object based on the object recognition result (S1120). In an embodiment, the simulator may generate a command capable of controlling a motion parameter (e.g., a position, a velocity, an acceleration, etc.) of a virtual unmanned moving object existing in a driving simulator environment according to the object recognition result.

Finally, the simulator may perform an autonomous driving simulation of the unmanned moving object based on the control command (S1130). In an embodiment, the simulator may input the control command to a dynamic model existing in the simulator and may perform a driving simulation that allows the virtual unmanned moving object having a motion parameter according to the control command to drive within the driving simulation environment. Each step S1110, S1120, and S1130 of the autonomous driving simulation method 1100 described above may be repeatedly performed until a sufficient simulation result is derived.

As in the above-described configuration, an object in a driving simulation environment may be modified by a time and a weather condition of the driving simulation environment set by a user, and an object recognition result for the object may be generated. In some embodiments, the generated object recognition result may be utilized to simulate an autonomous driving of an unmanned moving object. Accordingly, driving data under various conditions may be collected by replacing a test in an actual environment requiring a lot of time and resources, and a safety of an unmanned moving object (e.g., an autonomous vehicle, etc.) may be more efficiently verified.

A flowchart illustrated in FIG. 11 and the above-described description are only examples and may be implemented differently in some embodiments. For example, in some embodiments, an order of each step may be changed, some steps may be repeatedly performed, some steps may be omitted, or some steps may be added.

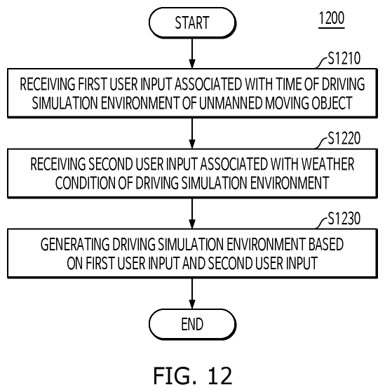

FIG. 12 is a flowchart illustrating an example of a driving simulation environment generating method 1200 according to an embodiment of the present disclosure. In an embodiment, the method 1200 may be performed by at least one processor (e.g., a processor 320) of an information processing system.

The method 1200 may be initiated by receiving a first user input associated with a time of a driving simulation environment of an unmanned moving object (S1210). In an embodiment, the first user input may include a user input associated with a first interface controlling the time of the driving simulation environment, the first interface may include a first toggle switch, the time of the driving simulation environment may be synchronized with a current time based on the first toggle switch being activated, a time control slider may be output (or displayed) on the first interface based on the first toggle switch being deactivated, and the time control slider may be configured such that the time of the driving simulation environment is adjusted corresponding to a slider value.

Then, the processor may receive a second user input associated with a weather condition of the driving simulation environment (S1220). In an embodiment, the second user input may include a user input associated with a second interface controlling the weather condition of the driving simulation environment, the second interface may include a second toggle switch, the weather condition of the driving simulation environment may be synchronized with a current weather condition of a specific region based on the second toggle switch being activated, and at least one weather control slider may be output on the second interface based on the second toggle switch being deactivated. In some embodiments, the second interface may further include at least one preset button for changing to a preset weather condition.

In an embodiment, the at least one weather control slider may include a first slider controlling a rainfall amount of the driving simulation environment and a second slider controlling a ground moisture amount of the driving simulation environment, and the second slider may be configured such that at least one of a number or a size of puddles existing on a ground of the driving simulation environment increases as a slider value increases, and at least one of a number or a size of puddles existing on the ground of the driving simulation environment decreases as the slider value decreases.

In an embodiment, the at least one weather control slider may include a third slider controlling a snowfall amount of the driving simulation environment and a fourth slider controlling a snow accumulation amount of a driving simulation environment, and the fourth slider may be configured such that a depth of snow accumulated in the driving simulation environment increases as a slider value increases, and the depth of snow accumulated in the driving simulation environment decreases as the slider value decreases.

In an embodiment, the at least one weather control slider may include a fifth slider controlling a density and a volume of clouds existing in the driving simulation environment, and the clouds existing in the driving simulation environment may be configured to spread out in an irregular radial shape around a specific reference position.

Finally, the processor may generate the driving simulation environment based on the first user input and the second user input (S1230). In an embodiment, the generated driving simulation environment may be utilized for an autonomous driving simulation of the unmanned moving object, and the autonomous driving simulation may be configured to recognize an object existing in the generated driving simulation environment, generate a control command associated with the unmanned moving object based on a recognition result of the object, and simulate an autonomous driving of the unmanned moving object based on the control command.

A flowchart illustrated in FIG. 12 and the above-described description are only examples and may be implemented differently in some embodiments. For example, in some embodiments, an order of each step may be changed, some steps may be repeatedly performed, some steps may be omitted, or some steps may be added.

The above-described method may be provided as a computer program stored in a computer-readable recording medium to execute on a computer. A medium may continuously store a computer-executable program or temporarily store the computer-executable program for execution or download. In some embodiments, the medium may be various recording means or storage means in a form in which one or more hardware components are combined but is not limited to a medium directly connected to a certain computer system and may be distributed and exist on a network. As an example of the medium, there may be a magnetic medium such as a hard disk, a floppy disk, and a magnetic tape, an optical recording medium such as a CD-ROM and a DVD, a magneto optical medium such as a floptical disk, and one configured to store a program instruction including a ROM, a RAM, a flash memory, and the like. In some embodiments, as an example of another medium, there may also be an app store that distributes applications, a site that supplies or distributes various other software, a recording medium, or a storage medium managed by a server, and the like.

Methods, operations, or techniques of the present disclosure may be implemented by various means. For example, these techniques may be implemented by a hardware, a firmware, a software, or a combination thereof. A person skilled in the art will understand that various exemplary logical blocks, modules, circuits, and algorithm steps described in connection with the disclosure herein may be implemented by an electronic hardware, a computer software, or combinations of both. To clearly describe such interchangeability of hardware and software, various exemplary elements, blocks, modules, circuits, and steps have been described above generally in terms of their functionality. Whether such a function is implemented as hardware or software depends on a specific application and design requirements imposed on an overall system. A person skilled in the art may implement the described functionality in various ways for each specific application, but such implementations should not be interpreted as causing a departure from a scope of the present disclosure.

In a hardware implementation, processing units used to perform the techniques may be implemented within one or more ASICs, DSPs, GPUs, digital signal processing devices (DSPDs), programmable logic devices (PLDs), field programmable gate arrays (FPGAs), processors, controllers, microcontrollers, microprocessors, electronic devices, other electronic units designed to perform the functions described in the present disclosure, a computer, or a combination thereof.

Therefore, various exemplary logical blocks, modules, and circuits described in connection with the present disclosure may be implemented or performed by a general-purpose processor, a DSP, an ASIC, an FPGA or other programmable logic device, discrete gate or transistor logics, discrete hardware components, or any combination thereof designed to perform the functions described herein. The general-purpose processor may be a microprocessor, but alternatively, the processor may be any conventional processor, a controller, a microcontroller, or a state machine. The processor may also be implemented as a combination of computing devices, for example, a combination of a DSP and a microprocessor, a plurality of microprocessors, one or more microprocessors in conjunction with a DSP core, or any other combination of configurations.

In a firmware and/or software implementation, the techniques may be implemented as instructions stored on a computer-readable medium such as a random access memory (RAM), a read-only memory (ROM), a non-volatile random access memory (NVRAM), a programmable read-only memory (PROM), an erasable programmable read-only memory (EPROM), an electrically erasable PROM (EEPROM), a flash memory, a compact disc (CD), a magnetic or optical data storage device, and the like. The instructions may be executable by one or more processors and may cause the processor(s) to perform specific aspects of the function described in the present disclosure.

When implemented in software, the techniques may be stored on a computer-readable medium or transmitted through the computer-readable medium as one or more instructions or codes. Computer-readable media include both computer storage media and communication media including any medium that facilitates a transfer of a computer program from one place to another place. The storage media may be any available media that may be accessed by a computer. As a non-limiting example, such a computer-readable medium may include a RAM, a ROM, an EEPROM, a CD-ROM or other optical disk storage, a magnetic disk storage or other magnetic storage devices, or any other medium that may be used to transport or store a desired program code in the form of instructions or data structures and that may be accessed by the computer. In some embodiments, any connection is properly termed a computer-readable medium.

For example, when software is transmitted from a website, a server, or another remote source using a coaxial cable, a fiber optic cable, a twisted pair, a digital subscriber line (DSL), or wireless technologies such as an infrared, a radio, and a microwave, the coaxial cable, the fiber optic cable, the twisted pair, the digital subscriber line, or the wireless technologies such as the infrared, the radio, and the microwave are included within the definition of a medium. A disk and a disc as used herein include a CD, a laser disk, an optical disk, a digital versatile disc (DVD), a floppy disk, and a Blu-ray disc, where disks usually reproduce data magnetically, whereas discs reproduce data optically using a laser. Combinations of the above should also be included within the scope of computer-readable media.

A software module may reside in a RAM memory, a flash memory, a ROM memory, an EPROM memory, an EEPROM memory, registers, a hard disk, a removable disk, a CD-ROM, or any other form of storage medium known in the art. An exemplary storage medium may be connected to a processor so that the processor may read information from the storage medium or write information to the storage medium. Alternatively, the storage medium may be integrated into the processor. The processor and the storage medium may reside within an ASIC. The ASIC may reside within a user terminal. Alternatively, the processor and the storage medium may reside in the user terminal as individual elements.

Although the above-described embodiments have been described as utilizing aspects of the presently disclosed subject matter in one or more standalone computer systems, the present disclosure is not limited thereto and may be implemented in connection with any computing environment such as a network or distributed computing environment. Furthermore, aspects of a subject matter in the present disclosure may be implemented in a plurality of processing chips or devices, and a storage may be similarly affected across a plurality of devices. Such devices may include PCs, network servers, and portable devices.

Hereinafter, technical features and technical effects of the present disclosure are further described to clarify a technical character of the present disclosure. In some embodiments, conventional driving simulation environment generating systems require a user to manually edit a plurality of low-level rendering parameters (e.g., shader parameters, particle system densities, post-processing values, light source coordinates, atmospheric scattering coefficients, etc.) through a developer-oriented configuration file or a complex parameter editor in order to reproduce a specific weather condition or a specific time zone. Such conventional approaches are time-consuming, prone to a human error, and impose a significant cognitive load on the user because the user is required to understand a relationship between the low-level rendering parameters and a final visual appearance of the driving simulation environment. In some embodiments, conventional approaches do not provide a means for synchronizing a state of the driving simulation environment with a real-world current time or a real-world current weather condition of a specific region in real time, which makes it difficult to efficiently generate a driving simulation environment matching a specific real-world scenario. As a result, an iterative testing of an autonomous driving algorithm under various weather conditions and time zones is hindered, and a verification efficiency of the autonomous driving algorithm is degraded.

According to an embodiment of the present disclosure, the first interface 130 and the second interface 140 provide a specifically structured graphical user interface that maps the plurality of low-level rendering parameters of the driving simulation environment to a small number of intuitively manipulable graphical control elements (e.g., the first toggle switch 410, the second toggle switch 430, the time control slider 420, the preset button 440, and the plurality of weather control slider sets 450, 460, and 470). The first toggle switch 410 may be configured such that, in response to being activated, an external real-time data source (e.g., a system clock of the driving environment simulation generating apparatus 110, a Network Time Protocol (NTP) server, a Global Positioning System (GPS) module, etc.) is queried and the time of the driving simulation environment is automatically synchronized with a real-world current time. The second toggle switch 430 may be configured such that, in response to being activated, an external weather information source (e.g., the OpenWeather API, the Korea Meteorological Administration short-term forecast API, etc.) is queried and the weather condition of the driving simulation environment is automatically synchronized with a real-world current weather condition of the specific region. According to such a configuration, the user may seamlessly switch between (i) a synchronization mode in which the driving simulation environment automatically reflects the real-world current time and the real-world current weather condition through the first toggle switch 410 and the second toggle switch 430, and (ii) a manual control mode in which the time and the weather condition of the driving simulation environment are precisely controlled through the time control slider 420, the preset button 440, and the plurality of weather control slider sets 450, 460, and 470, which has not been possible in the conventional simulation environment generating systems.

In some embodiments, the user interface 120 associated with the driving simulation environment generation improves a functioning of a computing device performing the driving simulation by reducing a number of user inputs and a processing load required for generating a driving simulation environment of a specific weather condition or a specific time zone. For example, in conventional approaches, in order to reproduce a snowy state having a specific snowfall amount and a specific snow accumulation amount, a plurality of separate parameter editing operations are required, each of which involves a sequence of menu navigation, parameter value input, and rendering parameter recompilation. In contrast, according to an embodiment of the present disclosure, the user may simultaneously and independently control the snowfall amount through the third slider 820 and the snow accumulation amount through the fourth slider 830 in a single integrated user interface, and a corresponding rendering of the driving simulation environment is automatically updated in response to a slider value change. Accordingly, an interaction efficiency between the user and the computing device is improved, and a number of computational cycles spent on a parameter editing and a rendering parameter recompilation is reduced. In some embodiments, decoupling the snowfall amount and the snow accumulation amount through two independent sliders enables a generation of a physically meaningful weather condition that is difficult to reproduce in a real environment, such as a state in which a current snowfall amount is small but the snow has accumulated to a substantial depth, or a state in which a current snowfall amount is large but the snow has not yet accumulated to a substantial depth. Such physically meaningful weather conditions are particularly useful for an edge-case verification of the autonomous driving algorithm. Similar technical effects are also provided by decoupling the rainfall amount and the ground moisture amount through the first slider 920 and the second slider 930.

In some embodiments, the generated driving simulation environment is not merely a result of an abstract data manipulation but is integrated into a specific technical process of verifying a safety and a reliability of an autonomous driving algorithm of an unmanned moving object. For example, the generated driving simulation environment is rendered through a virtual camera attached to a virtual unmanned moving object, an object recognition is performed on a rendered image, a control command is generated based on a recognition result of the object, and an autonomous driving simulation of the virtual unmanned moving object is performed based on the control command. The autonomous driving simulation may be performed iteratively under various weather conditions and time zones generated through the first interface 130 and the second interface 140, and a recognition performance of the autonomous driving algorithm and a control performance of the autonomous driving algorithm under each of the various weather conditions and time zones may be quantitatively evaluated. According to such a configuration, edge cases that are difficult to reproduce in an actual road test (e.g., a heavy snowfall with a small snow accumulation amount, a heavy rainfall with a small ground moisture amount, a low-visibility foggy state with a specific starting point distance, etc.) may be reliably reproduced in the driving simulation environment, and the autonomous driving algorithm may be verified for these edge cases. Accordingly, the generated driving simulation environment provides a meaningful improvement in the technical field of an autonomous driving algorithm verification, an unmanned moving object control, and an autonomous driving safety verification, by reducing a time and a resource required for the verification while improving a coverage of the verification.

In some embodiments, an autonomous driving simulation result obtained from the generated driving simulation environment may be used to update at least one parameter of the autonomous driving algorithm of the unmanned moving object. For example, when the recognition result of the object existing in the driving simulation environment is determined to be inaccurate under a specific weather condition (e.g., a heavy foggy state having a specific intensity, a heavy snowy state having a specific snow accumulation amount, etc.), at least one parameter of an object recognition model included in the autonomous driving algorithm may be updated based on the inaccurate recognition result, and an updated autonomous driving algorithm may be deployed to a real unmanned moving object. According to such a configuration, the generated driving simulation environment is integrated into an end-to-end technical pipeline of developing, verifying, and improving the autonomous driving algorithm, and the technical effect of the generated driving simulation environment is concretely realized as a tangible improvement of the autonomous driving algorithm operating in the real unmanned moving object.

According to various embodiments of the present disclosure, the driving simulation environment generated based on the first user input and the second user input provides at least the following technical effects when utilized for the autonomous driving simulation of the unmanned moving object. First, a verification time of the autonomous driving algorithm is reduced because an arbitrary weather condition may be instantly generated through the second interface 140 without waiting until a corresponding weather condition naturally occurs in a real-world environment or physically transporting the unmanned moving object to a region where the corresponding weather condition occurs. Second, a reproducibility of the verification of the autonomous driving algorithm is improved because an exact same weather condition may be reproduced multiple times by storing and reloading slider values of the time control slider 420 and the plurality of weather control slider sets 450, 460, and 470, which enables a controlled experiment of the autonomous driving algorithm. Third, a safety of the verification of the autonomous driving algorithm is improved because the autonomous driving algorithm may be verified under an extreme weather condition (e.g., a heavy storm state, a heavy snowy state with a high snow accumulation amount, a low-visibility foggy state, etc.) without any risk of a real-world accident. The above-described technical effects are not achievable by a generic computer performing a generic data manipulation but are achieved by the specifically structured user interface 120 in combination with the autonomous driving simulation pipeline of the unmanned moving object.

Although the present disclosure has been described herein in connection with some embodiments, various modifications and changes may be made without departing from a scope of the present disclosure that may be understood by a person skilled in the art to which the present disclosure pertains. In some embodiments, such modifications and changes should be considered as falling within the scope of the claims appended hereto.

What is claimed is:

1. A method performed by an apparatus for an unmanned moving object, the method comprising:
receiving:
a time-related user input associated with a time of a driving simulation environment of the unmanned moving object, and
a weather-related user input associated with a weather condition of the driving simulation environment;
synchronizing:
the time of the driving simulation environment with a current time, and
the weather condition of the driving simulation environment with a current weather condition of a specific region;
generating, based on the synchronized time and weather condition, the driving simulation environment; and controlling, based on the driving simulation environment, a simulated driving of the unmanned moving object.

2. The method of claim 1, wherein the time-related user input comprises a user input associated with a first interface controlling the time of the driving simulation environment,
wherein the first interface comprises a first toggle switch,
wherein the time of the driving simulation environment is synchronized with the current time based on the first toggle switch being activated,
wherein a time control slider is displayed on the first interface based on the first toggle switch being deactivated, and
wherein the time of the driving simulation environment is adjusted based on a slider value of the time control slider.

3. The method of claim 1, wherein the weather-related user input comprises a user input associated with a second interface controlling the weather condition of the driving simulation environment,
wherein the second interface comprises a second toggle switch,
wherein the weather condition of the driving simulation environment is synchronized with the current weather condition of the specific region based on the second toggle switch being activated, and
wherein at least one weather control slider is displayed on the second interface based on the second toggle switch being deactivated.

4. The method of claim 3, wherein the second interface further comprises at least one preset button for changing the weather condition to a preset weather condition.

5. The method of claim 3, further comprising:
controlling, by a first slider of the at least one weather control slider, a rainfall amount of the driving simulation environment; and
controlling, by a second slider of the at least one weather control slider and based on a slider value of the second slider, a ground moisture amount of the driving simulation environment such that:
at least one of a number of puddles or a size of the puddles existing on a ground of the driving simulation environment increases as the slider value increases, and
at least one of the number of the puddles or the size of the puddles decreases as the slider value decreases.

6. The method of claim 3, further comprising:
controlling, by a third slider of the at least one weather control slider, a snowfall amount of the driving simulation environment; and
controlling, by a fourth slider of the at least one weather control slider and based on a slider value of the fourth slider, a snow accumulation amount of the driving simulation environment such that:
a depth of snow accumulated in the driving simulation environment increases as the slider value increases, and
the depth of snow decreases as the slider value decreases.

7. The method of claim 3, further comprising:
controlling, by a fifth slider of the at least one weather control slider, a density of clouds and a volume of the clouds existing in the driving simulation environment, and
spreading out the clouds in an irregular radial shape around a specific reference position in the driving simulation environment.

8. The method of claim 1, further comprising:
recognizing an object existing in the driving simulation environment;
generating, based on the object, a control command for controlling the unmanned moving object; and
simulating, based on the control command, an autonomous driving of the unmanned moving object.

9. A non-transitory computer-readable medium recording instructions that, when executed, cause executing the method of claim 1.

10. An apparatus for an unmanned moving object, the apparatus comprising:
a communication circuit;
a processor; and
a memory storing instructions configured to be executed by the processor to cause the apparatus to:
receive:
a time-related user input associated with a time of a driving simulation environment of the unmanned moving object, and
a weather-related user input associated with a weather condition of the driving simulation environment,
synchronize:
the time of the driving simulation environment with a current time, and
the weather condition of the driving simulation environment with a current weather condition of a specific region,
generate, based on the synchronized time and weather condition, the driving simulation environment, and
control, based on the driving simulation environment, a simulated driving of the unmanned moving object.

11. The apparatus of claim 10, wherein the time-related user input comprises a user input associated with a first interface controlling the time of the driving simulation environment,
wherein the first interface comprises a first toggle switch,
wherein the time of the driving simulation environment is synchronized with the current time based on the first toggle switch being activated,
wherein the first interface is configured to, based on the first toggle switch being deactivated, display a time control slider, and
wherein the time control slider is configured to adjust, based on a slider value of the time control slider, the time of the driving simulation environment.

12. The apparatus of claim 10, wherein the weather-related user input comprises a user input associated with a second interface controlling the weather condition of the driving simulation environment,
wherein the second interface comprises a second toggle switch,
wherein the weather condition of the driving simulation environment is synchronized with the current weather condition of the specific region based on the second toggle switch being activated, and
wherein the second interface is configured to, based on the second toggle switch being deactivated, display at least one weather control slider.

13. The apparatus of claim 12, wherein the second interface further comprises at least one preset button for changing the weather condition to a preset weather condition.

14. The apparatus of claim 12, wherein the at least one weather control slider comprises:
a first slider configured to control a rainfall amount of the driving simulation environment; and
a second slider configured to control, based on a slider value of the second slider, a ground moisture amount of the driving simulation environment such that:
at least one of a number of puddles or a size of the puddles existing on a ground of the driving simulation environment increases as the slider value increases, and
at least one of the number of the puddles or the size of the puddles decreases as the slider value decreases.

15. The apparatus of claim 12, wherein the at least one weather control slider comprises:
a third slider configured to control a snowfall amount of the driving simulation environment; and
a fourth slider configured to control, based on a slider value of the fourth slider, a snow accumulation amount of the driving simulation environment such that:
a depth of snow accumulated in the driving simulation environment increases as the slider value increases, and
the depth of snow decreases as the slider value decreases.

16. The apparatus of claim 12, wherein the at least one weather control slider comprises a fifth slider configured to control a density of clouds and a volume of the clouds existing in the driving simulation environment, and
wherein the clouds are configured to spread out in an irregular radial shape around a specific reference position in the driving simulation environment.

17. The apparatus of claim 10, wherein the instructions are configured to be executed by the processor to cause the apparatus to:
recognize an object existing in the driving simulation environment,
generate, based on the object, a control command for controlling the unmanned moving object, and
simulate, based on the control command, an autonomous driving of the unmanned moving object.
